(19) United States
(12) Patent Application Publication
(10) Pub. No.: US 2019/0311921 A1
(43) Pub. Date: Oct. 10, 2019

(54) A PROCESSING APPARATUS AND A METHOD FOR CORRECTING A PARAMETER VARIATION ACROSS A SUBSTRATE

(71) Applicant: ASML NETHERLANDS B.V., Veldhoven (NL)

(72) Inventors: Everhardus Cornelis MOS, Best (NL); Jochem Sebastiaan WILDENBERG, Aarle-Rixtel (NL)

(73) Assignee: ASML NETHERLANDS B.V., Veldhoven (NL)

(21) Appl. No.: 16/340,702

(22) PCT Filed: Sep. 21, 2017
(86) PCT No.: PCT/EP2017/073867

§ 371 Date: Apr. 10, 2019

(30) Foreign Application Priority Data
Oct. 17, 2016 (EP) 16194224.8
Apr. 19, 2017 (EP) 17167041.7

(51) Int. Cl. H01L 21/67; G03F 7/20; H01L 21/677; H01L 21/687; H01L 21/68

(52) U.S. Cl. CPC H01L 21/67103; G03F 7/70625; H01L 21/68; H01L 21/67063; H01L 21/68764; H01L 21/67796

(57) ABSTRACT

A substrate processing apparatus includes a substrate loading device configured to load a substrate in a predetermined orientation relative to a grid, having a X-axis and an orthogonal Y-axis, associated with a layout of fields on the substrate; and corrective elements configured to enable local correction of a characteristic of a process performed on a substrate, wherein the corrective elements are arranged along at least one axis having a direction other than parallel to the X-axis or the Y-axis of the grid.

### CROSS-REFERENCE TO RELATED APPLICATIONS

This application claims priority of EP application 16194224.8 which was filed on Oct. 17, 2016 and EP application 17167041.7 which was filed on Apr. 19, 2017 which are incorporated herein in its entirety by reference.

### BACKGROUND

### Field of the Invention

The present invention relates to device manufacturing and in particular to improving the yield of a lithographic process

### Background Art

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. including part of a die, one die, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

In lithographic processes, it is desirable frequently to make measurements of the structures created, e.g. for process control and verification. Various tools for making such measurements are known, including: scanning electron microscopes, which are often used to measure critical dimension (CD); specialized tools to measure overlay, the accuracy of alignment of two layers in a device; and scatterometers which can measure various properties of patterned substrates.

Having measured a property, such as CD, across a substrate, known process optimization techniques adjust a related parameter of an exposure or process step to be carried out on the substrate or other substrates so as to correct or compensate for any error of that property. However, this approach is not always able to fully correct or compensate for errors.

### SUMMARY OF THE INVENTION

The present invention aims to improve yield in a lithographic device manufacturing process. The invention in a first aspect provides a substrate processing apparatus comprising:

a substrate loading device configured to load a substrate in a predetermined orientation relative to a grid associated with a layout of fields on the substrate;
corrective elements configured to enable local correction of a characteristic of a process performed on a substrate; characterized in that the corrective elements are arranged along at least one correction axis having a direction other than parallel to the X-axis or the Y-axis of the grid.
The invention in a second aspect provides a device manufacturing process comprising:

exposing a pattern onto a grid of fields on a substrate using a lithographic apparatus;

transporting the substrate to a process tool using a grid of corrective elements;

orienting the substrate so that the grid of fields is angled at a predetermined angle relative to the grid of corrective elements; and

transferring the pattern into the substrate using the process tool.

### BRIEF DESCRIPTION OF THE DRAWINGS/FIGURES

Embodiments of the invention will now be described, by way of example, with reference to the accompanying drawings in which:

FIG. 1 depicts a lithographic apparatus together with other apparatuses forming a production facility for semiconductor devices;

FIG. 2A depicts a substrate having target portions in a rectangular array;

FIG. 2B depicts a substrate oriented relative to a grid of zones of a process tool;

FIG. 2C depicts an arrangement of edge zones of a process device; and

FIG. 3 depicts a process of device manufacture according to an embodiment of the invention;

### DETAILED DESCRIPTION

Before describing embodiments of the invention in detail, it is instructive to present an example environment in which embodiments of the present invention may be implemented.

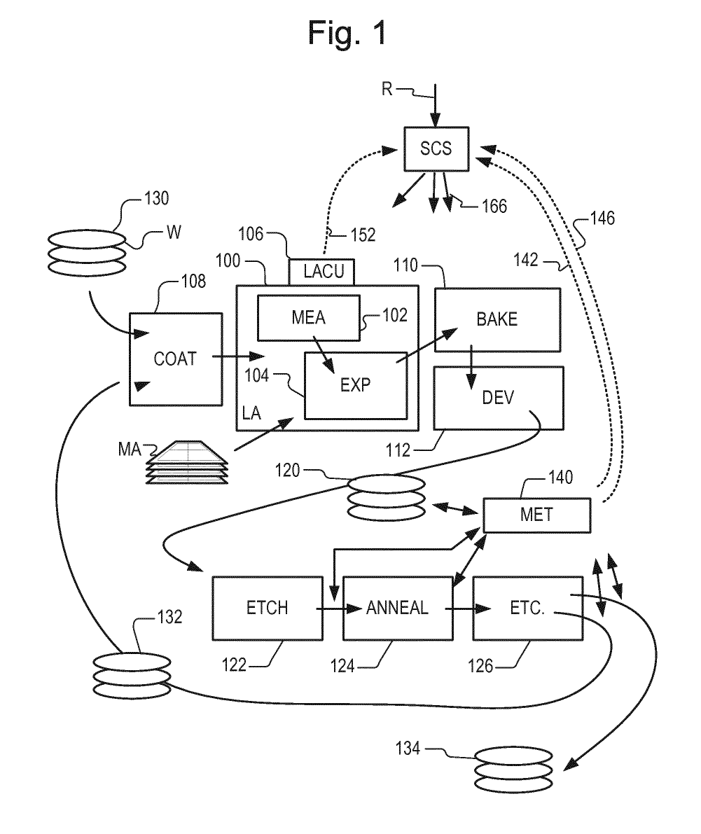

FIG. 1 illustrates a typical layout of a semiconductor production facility. A lithographic apparatus 100 applies a desired pattern onto a substrate. A lithographic apparatus is used, for example, in the manufacture of integrated circuits (ICs). In that instance, a patterning device, which is alternatively referred to as a mask or a reticle, comprises a circuit pattern of features (often referred to as “product features”) to be formed on an individual layer of the IC. This pattern is transferred onto a target portion (e.g., comprising part of, one, or several dies) on a substrate ‘W’ (e.g., a silicon wafer) via exposure 104 of the patterning device onto a layer of radiation-sensitive material (resist) provided on the substrate. In general, a single substrate will contain a network of adjacent target portions that are successively patterned.

Known lithographic apparatus irradiate each target portion by illuminating the patterning device while synchronously positioning the target portion of the substrate at an image position of the patterning device. An irradiated target portion of the substrate is referred to as an “exposure field”, or simply “field”. The layout of the fields on the substrate is typically a network of adjacent rectangles aligned in accordance to a Cartesian two-dimensional coordinate system (eg aligned along an X and an Y-axis, both axes being orthogonal to each other).

A requirement on the lithographic apparatus is an accurate reproduction of the desired pattern onto the substrate. The positions and dimensions of the applied product features need to be within certain tolerances. Position errors may occur due to an overlay error (often referred to as “overlay”). The overlay is the error in placing a first product feature within a first layer relative to a second product feature within a second layer. The lithographic apparatus minimizes the overlay errors by aligning each wafer accurately to a reference prior to patterning. This is done by measuring positions of alignment marks which are applied to the substrate. Based on the alignment measurements the substrate position is controlled during the patterning process in order to prevent occurrence of overlay errors.

An error in a critical dimension (CD) of the product feature may occur when the applied dose associated with the exposure 104 is not within specification. For this reason the lithographic apparatus 100 must be able to accurately control the dose of the radiation applied to the substrate. CD errors may also occur when the substrate is not positioned correctly with respect to a focal plane associated with the pattern image. Focal position errors are commonly associated with non-planarity of a substrate surface. The lithographic apparatus minimizes these focal position errors by measuring the substrate surface topography using a level sensor prior to patterning. Substrate height corrections are applied during subsequent patterning to assure correct imaging (focusing) of the patterning device onto the substrate.

To verify the overlay and CD errors associated with the lithographic process the patterned substrates are inspected by a metrology apparatus 140. A common example of a metrology apparatus is a scatterometer. The scatterometer conventionally measures characteristics of dedicated metrology targets. These metrology targets are representative of the product features, except that their dimensions are typically larger in order to allow accurate measurement. The scatterometer measures the overlay by detecting an asymmetry of a diffraction pattern associated with an overlay metrology target. Critical dimensions are measured by analysis of a diffraction pattern associated with a CD metrology target. Another example of a metrology tool is an electron beam (e-beam) based inspection tool such as a scanning electron microscope (SEM).

Within a semiconductor production facility, lithographic apparatus 100 and metrology apparatus 140 form part of a “litho cell” or “litho cluster”. The litho cluster comprises also a coating apparatus 108 for applying photosensitive resist to substrates W, a baking apparatus 110, a developing apparatus 112 for developing the exposed pattern into a physical resist pattern, an etching station 122, apparatus 124 performing a post-etch annealing step and possibly further processing apparatuses, 126, etc . . . The metrology apparatus is configured to inspect substrates after development (112) or after further processing (e.g. etching). The various apparatus within the litho cell are controlled by a supervisory control system SCS, which controls the lithographic apparatus via lithographic apparatus control unit LACU. The SCS allows the different apparatuses to be operated giving maximum throughput and product yield. An important control mechanism is the feedback 146 of the metrology apparatus 140 to the various apparatus (via the SCS), in particular to the lithographic apparatus 100. Based on the characteristics of the metrology feedback corrective actions are determined to improve processing quality of subsequent substrates.

The performance of a lithographic apparatus is conventionally controlled and corrected by methods such as advanced process control (APC) described for example in US2012008127A1. The advanced process control techniques use measurements of metrology targets applied to the substrate. A Manufacturing Execution System (MES) schedules the APC measurements and communicates the measurement results to a data processing unit. The data processing unit translates the characteristics of the measurement data to a recipe comprising instructions for the lithographic apparatus. This method is very effective in suppressing drift phenomena associated with the lithographic apparatus.

The processing of metrology data to corrective actions performed by the processing apparatus is important for semiconductor manufacturing. In addition to the metrology data also characteristics of individual patterning devices, substrates, processing apparatus and other context data may be needed to further optimize the manufacturing process. The framework wherein available metrology and context data is used to optimize the lithographic process as a whole is commonly referred to as part of holistic lithography. For example context data relating to CD errors on a reticle may be used to control various apparatus (lithographic apparatus, etching station) such that said CD errors will not affect the yield of the manufacturing process. Subsequent metrology data may then be used to verify the effectiveness of the control strategy and further corrective actions may be determined.

The use of metrology results is instrumental for the performance of a lithographic process. At the same time the requirements on the relevance of the metrology data are increasing with every shrink of the lithographic process.

An example of metrology results used to determine corrections to be applied by a lithographic apparatus is CD error measurements used to update optimal exposure settings of the lithographic apparatus. The corrective action is an adaptation of an exposure dose across a field or substrate (wafer). In many cases the adaptation is achieved by locally controlling an exposure dose fingerprint along the X-axis of the exposure fields (i.e. as a function of x position). In other cases an exposure dose fingerprint is controlled along the Y-axis (e.g. perpendicular to the X-axis) of the exposure fields (i.e. as a function of y position). The spatial coordinates in which the exposure dose adaptation is expressed is then defined with respect to a XY coordinate system associated with the exposure field layout on the substrate. In mathematical terms the exposure dose adaptation ED can be written as a superposition of a fingerprint adaptation F as a function of X and a fingerprint adaptation G as a function of Y:

ED(X,Y)=F(X)+G(Y)

Given the architecture of a lithographic apparatus, mostly equipped with corrective devices limited to correcting parameters (exposure dose) in one dimension, it is less obvious how to correct/control an exposure dose along directions other than parallel to the X or Y-axis. It will be appreciated that, for example, an adaptation function which includes terms including the product XY cannot be achieved by superposition of F(X) and G(Y).

After exposure of the substrate, the substrate is developed and features are formed in the resist layer. The characteristics of the features are measured by metrology tooling and depending on the deviation between a measured feature characteristic and a desired characteristic an additional corrective action is needed. As the feature is measured after development the term “After Development Inspection” (ADI) is often used to refer to measurements performed after resist development of the substrate.

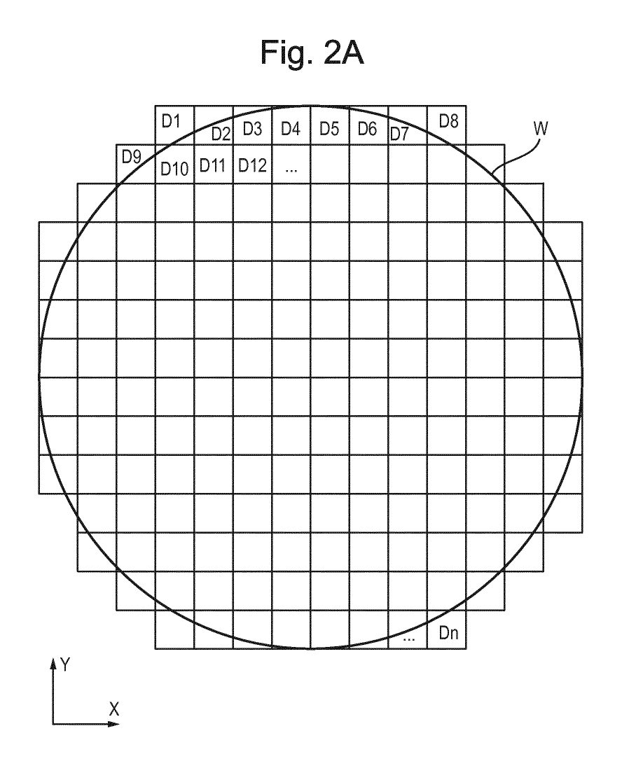

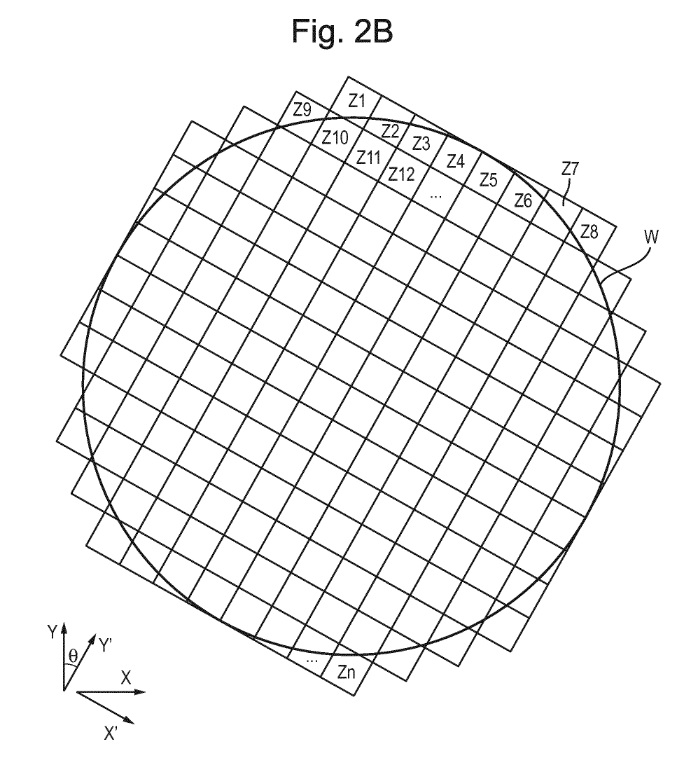

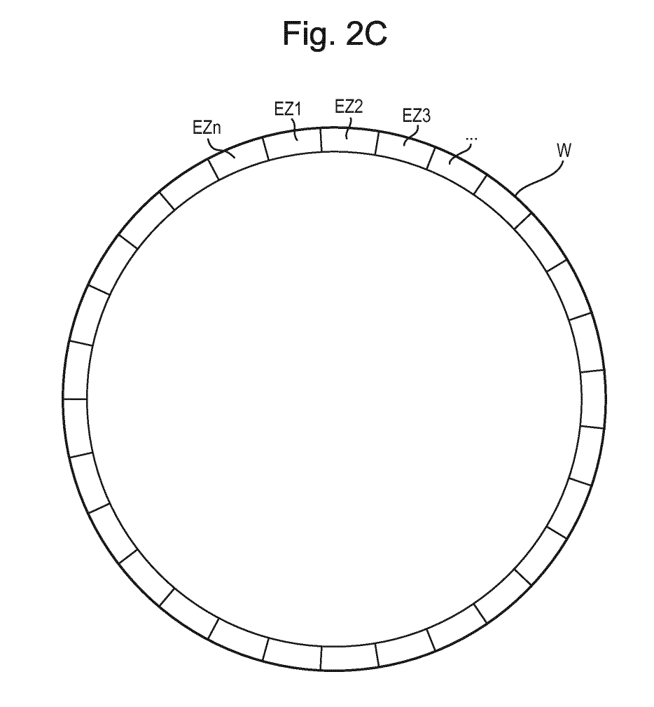

After development of the substrate, a number of process steps are performed in order to convert the layout of features in resist to a layout of functional semiconductor components. In analogy to a lithographic apparatus also other processing apparatus may be equipped with means to locally control characteristics of the to be formed features (components). An important example is the presence of multiple thermal zones within a substrate holder of an etching station (see FIG. 2b). The layout of the thermal zones is typically aligned with the field layout according to the exposures performed by the lithographic apparatus. By local control of the temperature of the substrate a local control of an etching characteristic on the substrate is achieved. In this way a certain spatial fingerprint of etched feature properties (CD) can be controlled. As with the control of the lithographic apparatus the adaptation of the etch characteristics EC can be expressed as superposition of a fingerprint H controlled in the X direction and a fingerprint J controlled in the Y-direction: EA(X,Y)=H(X)+J(Y). Given the architecture of the etching apparatus, equipped with corrective devices limited to correcting parameters (CD) per dimension, it is less obvious how to correct and/or control an etching characteristic (affecting the CD) along directions other than parallel to the X or Y-axis.

Also after etching process steps the characteristics of the etched features are measured using the metrology tool. As the metrology results relate to etched features the term “after etch inspection” (AEI) is often used to refer to measurements performed after an etching process step performed on the substrate.

The correction capabilities of the lithographic apparatus and the etching station may be taken into account when considering what corrective actions need to be applied based on the metrology results. In many cases the AEI results are most representative for the performance of the functional components and hence these results are considered in order to define what corrective actions to implement. The corrective actions of both the lithographic apparatus and the processing (etching) apparatus are potentially useful to improve the characteristics of the etched features. The challenge is to assign first corrective actions to a lithographic apparatus and additional second corrective actions to the other processing apparatus. The method to optimally assign corrective actions to the apparatus is often referred to as “co-optimization”; a correction strategy is chosen which gives the overall best result based on specific correction characteristics associated with the considered apparatus.

Essential to implementation of a successful co-optimization strategy is knowledge of the spatial characteristics of the corrective actions, both of the lithographic apparatus and of the other processing (etching) apparatus. In this context the term “correction grid” is introduced. The correction grid defines the principal axes along which a parameter variation can be corrected (for example a CD variation or an exposure dose variation). Typically for a lithographic apparatus the correction grid is aligned to the exposure field vertices. When both the lithographic apparatus and the etching station have similar correction grids (e.g. local control of feature characteristics is substantially limited to X and Y directions) co-optimization is likely to be of less added value then when both apparatuses have complimentary correction grids (e.g. do not have the same grid layout).

An illustrative example is the correction of a CD variation within an exposure field along the Y=X direction (45 degrees with X and Y-axis). When both the lithographic apparatus and the etching station are only capable of correcting CD variations along a X or Y direction, co-optimization of the lithographic apparatus and the etching station corrective elements will not substantially improve correction of the mentioned CD variation. In order to correct such a CD variation a fingerprint adaptation along a Y=X direction needs to be supported. In contrast to the previously discussed examples (ED(X,Y) and EA(X,Y)) such a correction can no longer be decomposed as a sum of an X-dependent and an Y-dependent contribution and hence a corrective element of a lithographic apparatus or other processing apparatus needs to be capable of adapting a fingerprint along the X-direction independent from a fingerprint adaptation along the Y-direction. Such a two-dimensional corrective element would however become more complex as it would need to utilize a large number of independently controllable pixel elements.

To avoid utilization of very complex corrective devices (either within a lithographic apparatus or another processing apparatus) it is proposed to maintain the use of simple one-dimensional corrective devices, but vary the orientation of the axes along which corrections can be applied between for example a lithographic apparatus and an etching apparatus. By doing so correction of fingerprints which are not aligned to the X and Y axes of a field layout can be supported to a greater extent than if both apparatus would have the same layout of corrective elements. Assuming that the lithographic apparatus has a fixed correction grid, a correction grid layout associated with a processing apparatus needs to be chosen with vertices which are not aligned with the exposure fields. The correction grid of the processing apparatus (in most cases an etching station) is defined by the layout of corrective elements (like heating elements) across the substrate holder or in close proximity to the substrate (for example voltage regulating devices affecting etching characteristics).

As an example of the proposed concept the layout of the exposure fields (lithographic apparatus) and the thermal zones of an etching apparatus are shown in FIG. 2. FIG. 2a shows a typical rectangular grid of exposure fields D1-D2n across a substrate. The grid of exposure fields D1-Dn is aligned with axis X and Y. FIG. 2b shows a first embodiment of the invention. FIG. 2b illustrates an arrangement of the thermal zones; the zones Z1-Zn are distributed on a grid which is rotated with respect to the correction grid associated with the lithographic apparatus. Zones Z1-Zn are disposed on a grid which is aligned to axes X′ and Y′ which are oriented at an angle θ to axes X and Y. This may be achieved by having the actual thermal zones rotated with respect to the substrate (holder). The orientation of the correction grid may be defined with reference to an axis thereof, which is referred to herein as the correction axis.

In a second embodiment of the invention a rotation of the correction grids is achieved by loading the substrate with a certain rotation unto the substrate holder of the etching station. This may be achieved by rotating the wafer on an effector element before placing it on the substrate holder. Standard alignment means may be provided to measure the rotation angle of the substrate (based on a position of a notch or a layout of exposure fields) with respect to the corrective elements. Note that the alignment of the substrate on loading of the substrate into the process device need not be as accurate as on loading into a lithographic apparatus. In many cases an angular tolerance of up to 1 or 2 or even 5 degrees may be acceptable. An advantage of this embodiment is a flexible selection of the angle θ between the correction grid of the processing apparatus and the grid associated with the field layout on the substrate. The angle θ may be chosen from a range of 45+/−45 degrees. An angle of 45 degrees would enable correction of a feature characteristic along a diagonal across the exposure field and/or substrate (relative to the nominal field layout associated with the lithographic apparatus).

FIG. 2c shows a third embodiment of the invention. Instead of a Cartesian based grid layout a polar grid layout defines the arrangement of the correction elements (thermal zones) associated with the processing apparatus.

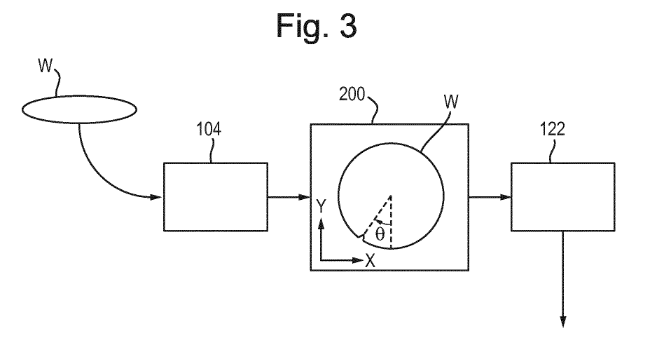

A method according to an embodiment of the invention is depicted in FIG. 3. A substrate is exposed to a device pattern by a lithographic apparatus at exposure 104. The exposed substrate is transported and loaded 200 into the process tool 122 to have the pattern formed in the exposure step transferred into the substrate. During the transport or loading or when the substrate is in the process tool 122 it is orientated so that the angle between a grid of fields on the substrate and a grid of corrective elements of the process tool is θ.

In a fourth embodiment of the invention a curvilinear correction grid layout is adopted. In a fifth embodiment a rectilinear grid layout is adopted.

Apart from a rotation between correction grids also other operations may be chosen to alter a correction grid for a first apparatus with respect to a correction grid of a second apparatus. In a sixth embodiment a mirroring operation is applied to a first correction grid to define a second correction grid.

While specific embodiments of the invention have been described above, it will be appreciated that the invention may be practiced otherwise than as described.

An embodiment may include a computer program containing one or more sequences of machine-readable instructions configured to instruct various apparatus as depicted in FIG. 1 to perform measurement and optimization steps and to control a subsequent exposure process as described above. This computer program may be executed, for example, within the control unit LACU or the supervisory control system SCS of FIG. 1 or a combination of both. There may also be provided a data storage medium (e.g., semiconductor memory, magnetic or optical disk) having such a computer program stored therein.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 1-100 nm), as well as particle beams, such as ion beams or electron beams. Implementations of scatterometers and other inspection apparatus can be made in UV and EUV wavelengths using suitable sources, and the present disclosure is in no way limited to systems using IR and visible radiation.

The term “lens”, where the context allows, may refer to any one or combination of various types of optical components, including refractive, reflective, magnetic, electromagnetic and electrostatic optical components. Reflective components are likely to be used in an apparatus operating in the UV and/or EUV ranges.

The following are exemplary embodiments of the invention:

A) A substrate processing apparatus comprising corrective elements configured to enable local correction of a characteristic of a process performed on a substrate, the substrate processing apparatus is characterized in that the corrective elements are arranged along at least one axis having a direction other than parallel to the X-axis or the Y-axis of a grid associated with a layout of fields on the substrate.

B) A substrate processing apparatus according to embodiment A), wherein the axis is oriented within a plane parallel to the substrate or a substrate holder surface of the substrate processing apparatus.

C) A substrate processing apparatus according to embodiment A) or B), wherein the axis is arranged at an angle of 45+/−40 degrees relative to the X-axis or Y-axis of the grid associated with the layout of fields on the substrate.

D) A substrate processing apparatus according to any preceding embodiment, further comprising means to rotate the substrate relative to the axis along which the corrective elements are arranged.

E) A substrate processing apparatus according to embodiment D), wherein the means allow selection of the angle of rotation between 0 and 90 degrees.

F) A substrate processing apparatus comprising corrective elements configured to enable local correction of a characteristic of a process performed on a substrate, the substrate processing apparatus is characterized in that the corrective elements are arranged according to a polar grid layout.

G) A substrate processing apparatus comprising corrective elements configured to enable local correction of a characteristic of a process performed on a substrate, the substrate processing apparatus is characterized in that the corrective elements are arranged according to a curvilinear or a rectilinear grid layout.

H) A substrate processing apparatus comprising corrective elements configured to enable local correction of a characteristic of a process performed on a substrate, the substrate processing apparatus is characterized in that the corrective elements are arranged according to a grid layout resulting from a mirror operation performed on a grid associated with a layout of fields on the substrate.

I) A substrate processing apparatus comprising corrective elements configured to enable local correction of a characteristic of a process performed on a substrate, the substrate processing apparatus is characterized in that the corrective elements are arranged according to a grid layout resulting from a scaling operation performed on a grid associated with a layout of fields on the substrate.

J) A method to optimize a semiconductor process, the method comprising a step of using the substrate processing apparatus according to any of embodiments A) to I).

The breadth and scope of the present invention should not be limited by any of the above-described exemplary embodiments, but should be defined only in accordance with the following claims and their equivalents.

1. A substrate processing apparatus comprising:
a substrate loading device configured to load a substrate in a predetermined orientation relative to a grid, having a X-axis and an orthogonal Y-axis, associated with a layout of fields on the substrate; and
corrective elements configured to enable local correction of a characteristic of a process performed on a substrate, wherein the corrective elements are arranged along at least one correction axis having a direction other than parallel to the X-axis or the Y-axis of the grid.

2. The substrate processing apparatus according to claim 1, wherein the correction axis is oriented within a plane parallel to the substrate or within a plane parallel to a substrate holder surface of the substrate processing apparatus.

3. The substrate processing apparatus according to claim 1, wherein the correction axis is arranged at an angle of 45+/−40 degrees relative to the X-axis or Y-axis of the grid.

4. The substrate processing apparatus according to claim 1, further comprising a rotation device configured to rotate the substrate relative to the correction axis.

5. The substrate processing apparatus according to claim 4, wherein the rotation device is configured to allow selection of the angle of rotation between 0 and 90 degrees.

6. A substrate processing apparatus comprising corrective elements configured to enable local correction of a characteristic of a process performed on a substrate, wherein the corrective elements are arranged according to a polar grid layout.

7. A substrate processing apparatus comprising corrective elements configured to enable local correction of a characteristic of a process performed on a substrate, wherein the corrective elements are arranged according to a curvilinear or a rectilinear grid layout.

8. A substrate processing apparatus comprising corrective elements configured to enable local correction of a characteristic of a process performed on a substrate, wherein the corrective elements are arranged according to a grid layout resulting from a mirror operation performed on a grid associated with a layout of fields on the substrate.

9. A method to optimize a semiconductor process, the method comprising using the substrate processing apparatus according to claim 1.

10. (canceled)

11. The method according to claim 9, wherein the substrate processing apparatus performs an etching operation.

12. The processing apparatus according to claim 1, configured to perform an etching operation.

13. The processing apparatus according to claim 6, configured to perform an etching operation.

14. The processing apparatus according to claim 7, wherein the corrective elements are arranged according to a rectilinear grid layout and a grid of fields on the substrate is angled at an oblique angle relative to the grid layout of the corrective elements.

15. The processing apparatus according to claim 14, wherein the grid of fields is arranged at an angle of 45+/−40 degrees relative to the grid layout of the corrective elements.

16. The processing apparatus according to claim 7, further comprising a rotation device configured to provide a rotation between a grid of fields on the substrate and the grid layout of the corrective elements.

17. The processing apparatus according to claim 7, configured to perform an etching operation.

18. The processing apparatus according to claim 8, wherein the grid layout of fields on the substrate is angled at an oblique angle relative to the grid layout of the corrective elements.

19. The processing apparatus according to claim 8, wherein the grid of fields is arranged at an angle of 45+/−40 degrees relative to the grid layout of the corrective elements.

20. The processing apparatus according to claim 8, further comprising a rotation device configured to provide a rotation between a grid of fields on the substrate and the grid layout of the corrective elements.

21. The processing apparatus according to claim 8, configured to perform an etching operation.
